(19) United States
(12) Patent Application Publication
(10) Pub. No.: US 2017/0308804 A1
(43) Pub. Date: Oct. 26, 2017

(54) METHOD AND APPARATUS FOR ADIABATIC QUANTUM ANNEALING

(71) Applicant: Nokia Technologies Oy, Espoo (FI)

(72) Inventors: Joachim WABNIG, Cambridge (GB); Antti NISKANEN, Espoo (FI)

(21) Appl. No.: 15/518,221

(22) PCT Filed: Oct. 8, 2015
(86) PCT No.: PCT/IB2015/057712

§ 371 Date: Apr. 10, 2017

(30) Foreign Application Priority Data
Oct. 20, 2014 (GB) 1418544.1

(51) Int. Cl. G06N 99/00; H01L 39/22; H01L 27/18

(52) U.S. Cl. CPC G06N 99/002; H01L 27/18; H01L 39/223

(57) ABSTRACT

An approach is provided for adiabatic quantum annealing (computing, AQC). There is disclosed an apparatus comprising a first quantum dot and a second quantum dot forming a first kind of double quantum dot; and a third quantum dot and a fourth quantum dot forming a second kind of double quantum dot. The apparatus also comprises a first control element for adjusting a capacitance of a capacitive element; a second control element for supplying a control voltage to the first kind of double quantum dot; a metallic or superconducting contact to capacitively couple the first kind of double quantum dot to the fourth quantum dot; and an electric charge sensor for providing an indication of the state of the first kind of double quantum dot. The present invention also relates to a method for controlling the apparatus.

### TECHNOLOGICAL FIELD

The present invention relates generally to adiabatic quantum annealing (computing, AQC). More particularly, the present invention relates to a method for finding a solution by using adiabatic quantum annealing. The present invention also relates to apparatuses and computer program products for implementing the method and circuitry relating to the adiabatic quantum annealing.

### BACKGROUND

This section is intended to provide a background or context to the invention that is recited in the claims. The description herein may include concepts that could be pursued, but are not necessarily ones that have been previously conceived or pursued. Therefore, unless otherwise indicated herein, what is described in this section is not prior art to the description and claims in this application and is not admitted to be prior art by inclusion in this section.

Adiabatic quantum annealing is a technology for efficiently finding good solutions to discrete optimization problems. Such problems may be both extremely awkward for digital computers and important. Many cutting-edge artificial intelligence (AI) involves solving such problems. Adiabatic quantum annealing may solve binary optimization problems and may accelerate sampling from a Boltzmann machine.

Adiabatic quantum annealing is a hardware-accelerated method for solving difficult discrete optimization problems. The idea of adiabatic quantum annealing may be adapted to superconducting quantum circuits. Adiabatic quantum annealing is different from other optimization methods in that it may benefit from quantum tunneling to escape from local minima of the objective function.

### SOME EXEMPLARY EMBODIMENTS

Examples of hardware architecture for discrete optimization and a programming method are provided. Specifically, examples are provided which represent a variant of adiabatic quantum annealing.

An aim is to obtain long range tunable coupling between double quantum dot based charge qubits for adiabatic quantum annealing, and to obtain a fully connected coupling graph between the individual qubits with only a small number of necessary electrical control lines.

According to one embodiment, an apparatus comprises

a first quantum dot and a second quantum dot forming a first kind of double quantum dot;

a third quantum dot and a fourth quantum dot forming a second kind of double quantum dot for providing adjustable capacitance for the first double quantum dot;

a first control element for adjusting the capacitance of the second kind of double quantum dot;

a second control element for supplying a control voltage to the first kind of double quantum dot;

a metallic or superconducting contact capacitively coupled to the fourth quantum dot; and

a quantum point contact for providing an indication of the state of the first kind of double quantum dot.

According to one embodiment, a method comprises

supplying a control voltage to a plurality of first kind of double quantum dots of an apparatus, said first kind of double quantum dots comprising a first quantum dot and a second quantum dot;

adjusting a capacitance for the first kind of double quantum dots to a metallic or superconducting contact by using a plurality of second kind of double quantum dots;

decreasing tunneling in the first kind of double quantum dots; and

using an electric charge sensor for obtaining an indication of the state of the first kind of double quantum dot.

According to one embodiment, an apparatus comprises

a first quantum dot and a second quantum dot forming a first kind of double quantum dot;

a third quantum dot and a fourth quantum dot forming a second kind of double quantum dot for providing adjustable capacitance for the first double quantum dot;

means for adjusting the capacitance of the capacitive element;

means for supplying a control voltage to the first kind of double quantum dot;

means for coupling the first kind of double quantum dot to a metallic or superconducting contact; and

means for providing an indication of the state of the first kind of double quantum dot.

Still other aspects, features, and advantages of the invention are readily apparent from the following detailed description, simply by illustrating a number of particular embodiments and implementations.

The invention is also capable of other and different embodiments, and its several details can be modified in various obvious respects, all without departing from the spirit and scope of the invention. Accordingly, the drawings and description are to be regarded as illustrative in nature, and not as restrictive.

There is provided examples of a scalable architecture for adiabatic quantum annealing based on quantum dots. An advantage of employing a bus coupler is that a large number of qubits can be connected. According to an example implementation, due to the small size of the elementary building block (about 1 μm) up to 10⁶ bits can fit in an area of 1 mm².

### BRIEF DESCRIPTION OF THE DRAWINGS

The embodiments of the invention are illustrated by way of example, and not by way of limitation, in the figures of the accompanying drawings:

FIG. 1 is an illustration of an example of a coupling between two double quantum dot charge qubits via a capacitive bus according to an exemplary embodiment;

FIG. 2 is an illustration of an example of coupling between N double quantum dot charge qubits via a capacitive bus according to an exemplary embodiment;

FIG. 3 illustrates how a variable capacitance may be mediated by an additional conductor;

FIG. 4 is an illustration of a possible realization of the capacitive coupling;

FIG. 5 is another illustration of a possible realization of the capacitive coupling;

FIG. 6 depicts an example of a layout of a Boltzmann machine incorporating several layers;

FIG. 7 is an illustration of a possible connectivity involving several bus couplers;

FIG. 8 depicts an example of an arrangement of gates that enables tuning of the variable capacitance and the bias for the qubit;

FIG. 9 depicts an example of a multiplexer;

FIG. 10 depicts an example implementation of a multiplexer;

FIG. 11 depicts an example of a qubit readout mechanism using a quantum point contact;

FIG. 12 depicts an example of an electrical circuit diagram of a readout mechanism;

FIG. 13 illustrates of an example of operation of a readout scheme;

FIG. 14 depicts an example layout of a functional 8 bit quantum annealing cell;

FIG. 15 is an illustration of a structure of a set of qubits of an adiabatic quantum annealing processor and some interactions between the qubits;

FIG. 16 is an illustration of changing from an initial Hamiltonian to a final problem Hamiltonian with a computationally relevant ground state;

FIG. 17 is a diagram of some components of a computing apparatus comprising one or more sets of qubits according to an exemplary embodiment;

FIG. 18 is another diagram of some components of a computing apparatus comprising one or more sets of qubits according to an exemplary embodiment;

FIG. 19 is an example of an arrangement for communication comprising a plurality of apparatuses, networks and network elements.

### DESCRIPTION OF EXAMPLE EMBODIMENTS

In the following description, for the purposes of explanation, some specific details are set forth in order to provide a thorough understanding of the embodiments of the invention. It is apparent, however, to one skilled in the art that the embodiments of the invention may be practiced without these specific details or with an equivalent arrangement. In other instances, well-known structures and devices are shown in block diagram form in order to avoid unnecessarily obscuring the embodiments of the invention.

Embodiments are provided to show how to implement in hardware long range tunable coupling between double quantum dot based charge qubits for adiabatic quantum annealing, and how to provide a fully connected coupling graph between the individual qubits with only a small number of electrical control lines. An idea is to introduce a metallic structure as a bus to couple a large number of quantum dots. Double quantum dots may be used to realize a variable capacitance. An example embodiment provides special arrangement of metallic islands which enable a change of the coupling from ferromagnetic to antiferromagnetic. When using several buses a multipartite connectivity graph may also be enabled.

In an example embodiment of a method a control of N couplings and biases within the cryogenic environment may be enabled with only O(log N) control lines. There is also disclosed a method which uses time multiplexing for reading out N qubits with only 2 additional connections to the O(log N) control lines.

Compared to computation by conventional computer, quantum computation is based on quantum information processing by quantum bits (qubit). A qubit can be_in two distinct states (representing a logical 0 or 1), or in a quantum superposition state. The quantum superposition state means that the state of the qubit is not yet settled, or it can also be imagined that the qubit is in both states 0 and 1 at the same time. The superconducting qubit structure encodes the two states as tiny magnetic fields, which either point up or down. These states can be called, for example, +1 and −1, and they correspond to the two states that the qubit can ‘choose’ between. Using the quantum mechanics that is accessible with these structures, this object can be controlled so that the qubit can be put into a superposition of these two states. So by adjusting a control knob on a quantum computer, all the qubits can be put into a superposition state where it hasn't yet decided which of those +1, −1 states to be.

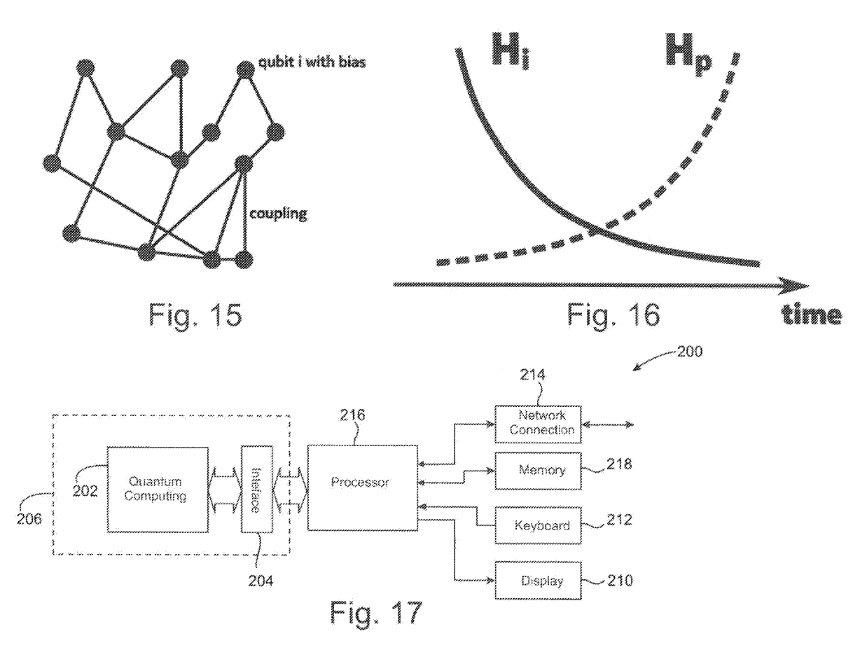

FIG. 15 is a simplified illustration of a structure of a set of qubits of an adiabatic quantum annealing processor and some interactions between the qubits. The basic layout of such adiabatic quantum annealing processor consists of a number of quantum bits (qubits). The energy of the set of qubits may be given by local biases and couplings between qubits. The interactions can be represented as a graph, as illustrated in FIG. 15. In some example implementations of the adiabatic quantum annealing processors only adjacent qubits may easily be coupled to each other.

Adiabatic annealing process may consist of continuously changing an initial Hamiltonian Hᵢ with an easily accessible ground state to a final problem Hamiltonian Hₚ with a computationally relevant ground state. The changeover from one Hamiltonian to the other may be done in such a way that the system remains in the ground state. This is illustrated in FIG. 16. An example choice for the initial Hamiltonian H, is for only local biases that induce a quantum mechanical superposition in the computational basis in the qubits.

In the following chip architecture is discussed in more detail.

Chip Architecture

According to an example embodiment an adiabatic quantum optimization device may consist of an array of computational elements. Individually, each such element, or quantum bit (qubit), can be in two distinct states, or in a quantum superposition state. The qubits may be individually addressable in two ways. The relative energy of their two different computational states may be adjustable. Also, each qubit's state may be measurable using a quantum measurement device. In order to be able to perform non-trivial computations, the interaction energy of some elements may be adjustable. This is analogous to having a ferromagnetic or antiferromagnetic adjustable coupling between artificial (or real) magnetic dipoles. Collectively, the system can exhibit superpositions of multi-qubit states and entanglement. For instance, the energy eigenstates can be entangled.

Overall, the computational apparatus thus has a total energy function, or a Hamiltonian operator given by

H=Σᵢ₌₁^{M}Σⱼ₌₁ⁱ⁻¹Jᵢⱼσ_{z}ⁱσ_{z}^{j}+Σⱼ₌₁^{M}Bⱼσ_{z}^{j} (1)

Here σ_{z}ⁱ stands for the Pauli z-matrix and hⱼ is the associated programmable energy bias of qubit j. The interaction energies are encoded in the programmable coupling matrix Jᵢⱼ. Two qubits are coupled in a tunable way if the respective matrix element is both adjustable and non-zero. Note that the matrix defines a graph with weighted and signed edges. An example of this is illustrated in FIG. 15.

The basic computational principle is to encode a problem of interest in the energy function. The result of the computation is a low energy, or ideally, the lowest energy configuration of the array of qubits given the restrictions set by the adjustable energy terms.

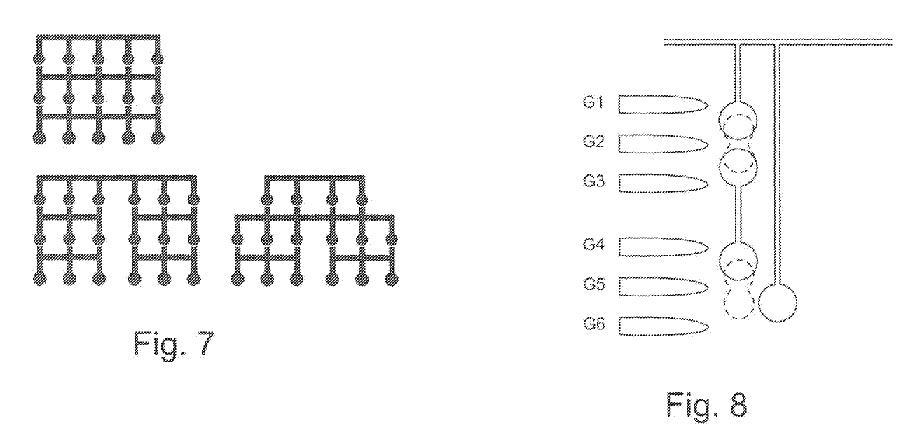

However, achieving this may not be easy. While the physical computational device may be e.g. cryogenically cooled and may sit in a shielded environment, the computer may need an annealing step to find a good solution. To this end, an additional external parameter may be used to adiabatically (slowly) transform the energy function from an initialization Hamiltonian to the target Hamiltonian, as is illustrated in FIG. 7.

To achieve the adiabatic quantum annealing, the following time-dependent Hamiltonian may be used.

$$H ( t ) = f ( \frac{t}{T} ) H + f ( \frac{t - T}{T} ) {H}_{i} \qquad ( 2 )$$

Here T is the total time for the annealing schedule and H, is the initial Hamiltonian. It may be, for instance, given by H=ΔΣⱼ₌₁^{N}σₓ^{j}, where σₓ^{j} is the Pauli x-matrix and A is an energy scale. After the annealing, at time t=T the bits will be in a particular configuration and generally one may expect to generate a number of configurations according to a probability distribution. One may then assume that the samples as if they were drawn from a Boltzmann machine. All of this may be implemented with e.g. superconducting circuits. The qubit energy scales may be, for example, less than 10 GHz, while the thermal environment may accordingly be around 10 mK. This may be achieved using e.g. a dilution refrigerator,

To summarize, a chip that implements quantum annealing may need to meet several requirements. Well defined qubits (level width less than the energy splitting); Ability to tune bias energies for individual qubits in the computational basis (z-basis); Ability to adjust couplings between qubits in the computational basis (z-basis); Ability to adjust tunneling between computational basis states collectively and time-dependent; High fidelity read-out of the qubits in the computational basis.

Quantum Dots

Quantum dots are small metallic or semiconductor islands that show quantized energy levels due to their small size. A small number (down to one) of electrons can be confined and manipulated in quantum dots. The spin degree of freedom or the charge degree of freedom of the electron can be used to encode information (spin and charge qubits). Due to the small size and good isolation quantum effects can be observed in quantum dots. This makes them a good platform for quantum computing.

An interesting property of double quantum dots is quantum capacitance, a capacitance that does not depend on the geometric layout of the quantum dot, but arises from the tunneling dependent energy level curvature of the double quantum dot. The magnitude of this capacitance can be tuned by adjusting the tunneling between the two dots and the electrostatic potential of the two dots.

Different implementations of quantum dot qubits may be provided, also in different material platforms such as GaAs, Si, SiGe, nanotubes and graphene.

Charge based qubits in double quantum dots are a promising technology for adiabatic quantum annealing. Sufficiently long coherence times have been demonstrated and an adiabatic quantum annealing processor based on quantum dots could be manufactured with well-known semiconductor processing techniques.

In an adiabatic quantum annealing processor based on double quantum dot charge qubits, information may be encoded in the location of a charge in a double quantum dot. For example, qubit value zero may correspond to an electron located in dot 1, qubit value 1 to an electron located in dot 2.

Basics of Indirect Capacitive Coupling

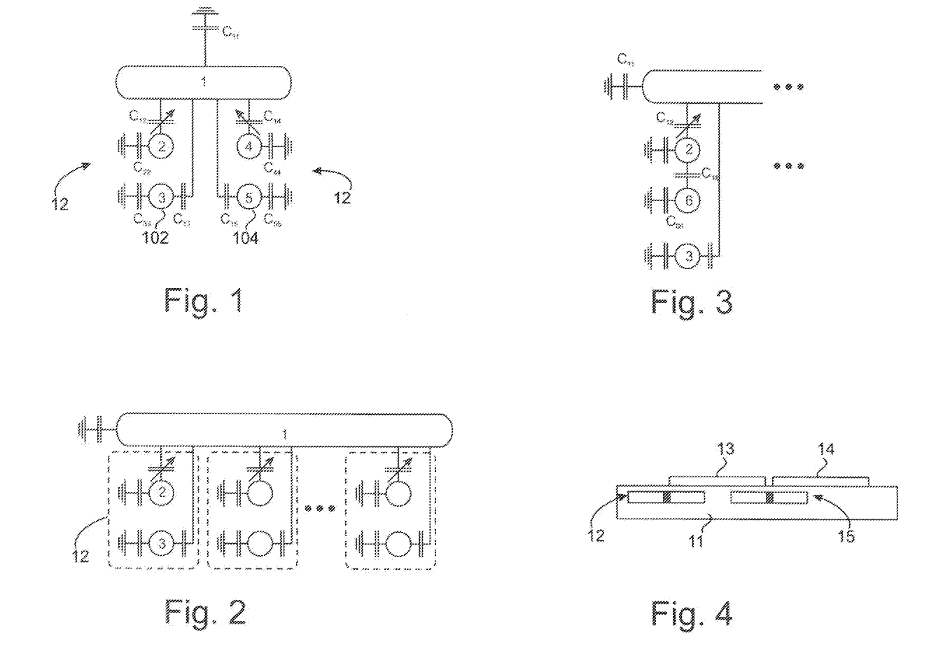

To mediate the interaction between two charge qubits a third element may be used, namely a coupling bus that couples capacitively to the two qubits. The interaction of two qubits and a bus can be described in terms of the mutual and self-capacitances (see FIG. 1). The capacitance matrix of the five conductors is then given by

$$C = ( \begin{matrix}{C}_{11} + {C}_{12} + {C}_{13} + {C}_{13} + {C}_{15} & - {C}_{12} & - {C}_{13} & - {C}_{14} & - {C}_{15} \\ - {C}_{12} & {C}_{22} + {C}_{12} & 0 & 0 & 0 \\ - {C}_{13} & 0 & {C}_{33} + {C}_{13} & 0 & 0 \\ - {C}_{14} & 0 & 0 & {C}_{44} + {C}_{14} & 0 \\ - {C}_{15} & 0 & 0 & 0 & {C}_{55} + {C}_{15}\end{matrix} ) \qquad ( 3 )$$

Assuming that the island does not have a considerable capacitance to ground, C₁₁ can be set to zero. For similar sized dots also C₀₀=C₂₂=C₃₃=C₄₄=C₅₅. Furthermore, the fixed capacitance between the island and the dots should be of similar size (C₁₃=C₁₅=a C₂₂). The variable capacitances may then be expressed in terms of the dot self-capacitance (C₁₂=x C₂₂, C₁₄=y C₂₂). The energies for a certain charge configuration Q=(q1, q2, q3, q4, q5) are then given by

Eᵢ=½Qᵢ·C⁻¹Qᵢ (4)

with the charge configurations
Q₁=e(0, 1, 0, 1, 0), Q₂=e(0, 1, 0, 0, 1), Q₃=e(0, 0, 1, 1, 0), Q₄=e(0, 0, 1, 0, 1)

This can be compared with the energy of different bit configurations according to Eq. (1).

E₁=−B₁−B₂+J+E₀,E₂=−B₁+B₂−J+E₀,E₃=B₁−B₂−J+E₀,E₄=B₁+B₂+J+E₀ (5)

The tunable qubit interaction may be deduced as a function of the tuning parameters a, x, y as

$$J = - \frac{{e}^{2}}{2 {C}_{00}} \frac{( a - x ) ( a - y )}{( 1 + a ) [ ( 2 a + 1 ) ( x + y + 2 xy ) + a ( 2 + x + y ) ]} = - \frac{{e}^{2}}{2 {C}_{00}} \frac{{C}_{00}^{5}}{det C} ( a - x ) ( a - y ) \qquad ( 6 )$$

The denominator of this expression is positive. In order to change the sign of the coupling x and y have to be tunable from values smaller than a to values larger than a.

For N qubits connected to a bus (see FIG. 2) the coupling between two individual qubits becomes

$${J}_{ij} = \frac{{e}^{2}}{2 {C}_{00}} ( a - {x}_{i} ) ( a - {x}_{j} ) \frac{{C}_{00}^{2 N + 1}}{det C} {( 1 + a )}^{N - 2} {\prod }_{k \neq i , j}^{N} ( 1 + {x}_{k} ) \qquad ( 7 )$$

where the xₖ are the dimensionless variable capacitances C₁ₖ/C₀₀. The coupling strength decreases with the number of qubits approximately linearly.

For a charging energy

$${E}_{Q} = \frac{{e}^{2}}{2 {C}_{00}} \approx 10 meV \qquad ( 8 )$$

and a=½, xₖ=1 a coupling strength may be obtained as

$$J \approx \frac{1}{6 N} meV \qquad ( 9 )$$

Assuming that the maximum coupling strength is to be about J=5 kT this gives a possible number of

$$N \approx 0.5 \frac{1}{T} \qquad ( 10 )$$

which allows the coupling of approximately 50 qubits to the bus at 10 mK.

It should be noted that adjusting the capacitances not only influences the couplings Jᵢⱼ but also the biases Bᵢ, Bⱼ. If only the coupling Jᵢⱼ is to be adjusted, a compensating bias may need to be applied to the involved bits.

Using a Double Quantum Dot as a Variable Capacitance

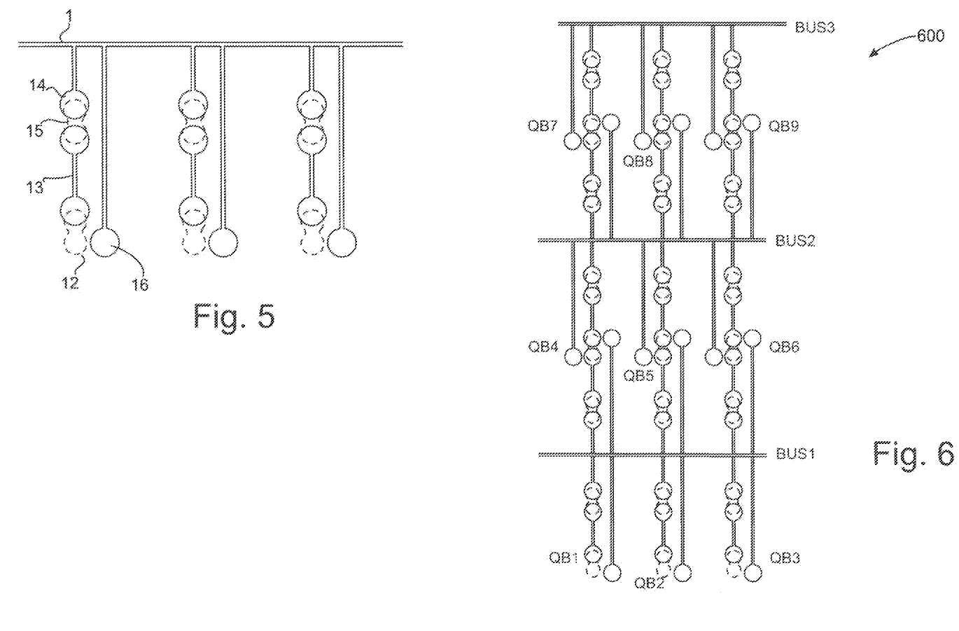

A double quantum dot can act as a controllable capacitance. The double quantum dot acting as a coupler can be capacitively coupled to the qubit double quantum dot. One can use an additional metallic gate to enhance the coupling between the qubit double quantum dot and the double dot acting as a variable capacitance. The capacitances are then connected as shown in FIG. 3. The layout on the chip is shown in section in FIG. 4 and in projection in FIG. 5. The metallic islands should be designed in a way that most of their capacitance is concentrated close to the quantum dots to ensure stronger coupling.

Using Several Buses and Interconnectivity

The qubit double quantum dots and their coupler double quantum dots can be arranged in a layered structure as shown in FIG. 6. Examples of different connectivity involving bus couplers are shown in FIG. 7. The length of the bus coupler is limited by the relative capacitance of the patches coupling to the quantum dots and the wires in between. Within a unit cell the geometric capacitance of a patch may be smaller than the geometric capacitance of the wire

$$\frac{{C}_{wire}}{{C}_{disc}} = \frac{2 π l}{ln ( l / a8r )} \qquad ( 11 )$$

where r is the radius of the disc, l is the length of the wire and a is the width of the wire.

Measuring the length of the wire in disc radius 1=x r and fixing the width of the wire to a=0.1 r the following equation may be obtained

$$\frac{{C}_{wire}}{{C}_{disc}} = \frac{x}{ln ( 10 x )} \qquad ( 12 )$$

which allows a wire length of 1≈2-3 r per unit cell.

Providing the Voltage Bias for Gates

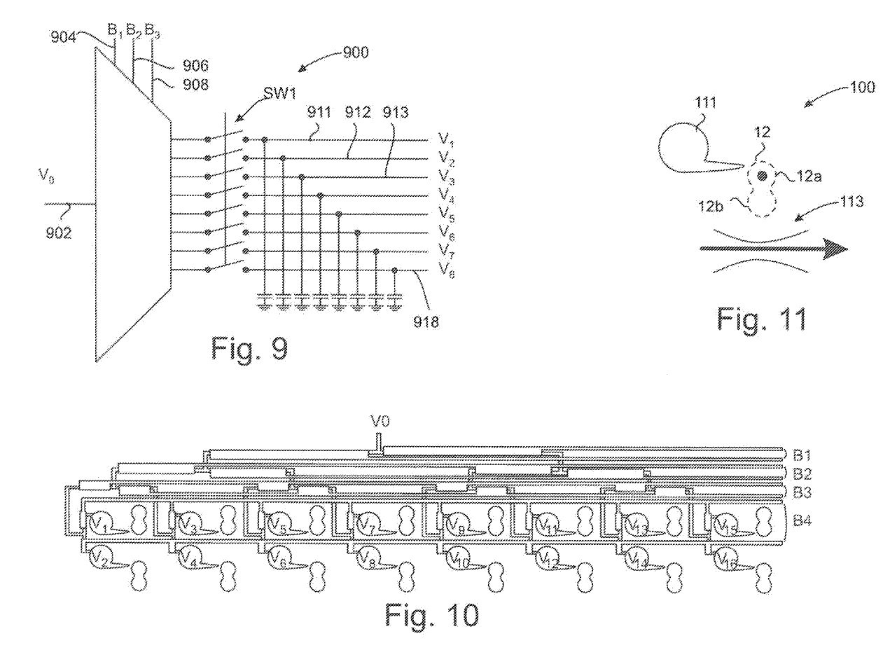

For a unit cell of one qubit at least 2 (up to 6) voltages may need to be supplied to be able to adjust the coupling capacitance and the qubit bias (see FIG. 8). For a large number of qubits this may require a large number of control lines, which may make it difficult to supply all voltages from outside the cryogenic environment. A multiplexing scheme may be used to reduce the number of necessary control lines from N to O(log N). The scheme is outlined in FIG. 9. FIG. 10 shows an example layout implementing the multiplexing scheme for the use of biasing double quantum dots. The capacitor needs to hold the charge for the time of an annealing run. With a given leakage current this determines the necessary size of the capacitor. The size of the capacitor can be reduced if the charge is refreshed during the annealing time.

A biasing protocol would work like this:

1. Choose the right addressing bit combination for the gate that needs to be biased and apply the combination on terminals B1-BN.
2. Apply the desired bias voltage V0 for long enough time that the gate capacitance is charged.
3. Move to the next gate or disconnect all gate capacitors from the biasing lines when finished.

Readout

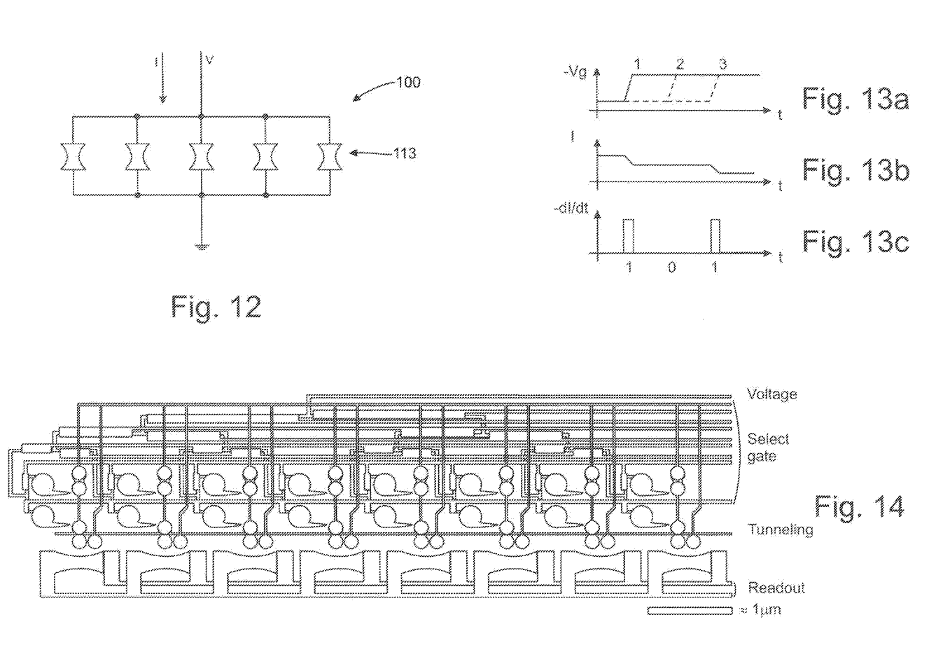

To read out the result of the computation the charge state of each qubit needs to be determined. This can be done by using a sensitive charge detector in the vicinity of the double quantum dot. Possible candidates for charge detectors are quantum point contacts (QPCs) and single electron transistors (SETS). A problem may arise when a large number of qubits have to be read out, since having individual control over each charge detector may require a large number of control lines. Hence, to overcome this a multiplexed scheme for readout may be used. The building blocks for the readout according to an example embodiment are shown in FIG. 11. FIG. 12 shows how the readout elements are connected electrically. FIG. 12 introduces the time multiplexed readout scheme.

Instead of measuring the current, the derivative of the current can be probed directly using lock-in techniques.

A readout protocol might work like this.

1. Apply a voltage at terminal V0.
2. Apply a bias voltage to the quantum point contacts.
3. Cycle through all combinations of voltages that address a qubit bias gate.
4. Record the current or its derivative through the QPCs.

FIG. 1 is an illustration of a coupling between two double quantum dot charge qubits 12 arranged via a capacitive bus 1. The left double dot 102 is formed by the conductors 2 and 3, the right double dot 104 by the conductors 4 and 5. A bus conductor 1 couples to conductors 2 and 4 via a variable capacitance C₁₂, C₁₄ and to conductors 3 and 5 via a fixed capacitance (C₁₃, C₁₅). This layout may allow the coupling between qubits 12 to change from ferromagnetic to antiferromagnetic. Additionally each conductor 1-5 may have a certain capacitance to ground. These capacitances are illustrated by C₁₁, C₂₂, C₃₃, C₄₄ and C₅₅ in FIG. 1.

FIG. 2 is an illustration of an example of a coupling between N double quantum dot charge qubits 12 via a capacitive bus 1. The basic structure of each qubit 12 and the coupling to the bus conductor 1 may be similar to the structure of the qubits 12 and the coupling of FIG. 1, respectively.

FIG. 3 illustrates how the variable capacitance C₁₂, C₁₄ may be mediated by an additional conductor 6. The additional conductor 6 has a capacitance C₁₆ to the conductor 2 of the qubit of FIG. 2 and a capacitance C₆₆ to the ground.

FIG. 4 illustrates as a sectional view an example of a realization of the capacitive couplings. According to this example a double quantum dot 12 is embedded in substrate 11 so that the substrate surrounds the double quantum dot 12. Above the double quantum dot 12 a part 13 is formed of a metallic substance by some appropriate method, e.g. by depositing. This metallic part 13 may also be called as a metallic or superconducting island or a metallic or superconducting gate in this specification. The metallic part 13 is deposited on top of the substrate 11 so that it covers the area of mostly one quantum dot of the double quantum dot 12. This metallic part 13 also covers a part of a second quantum dot 15, e.g. the area of mostly one quantum dot of the second double quantum dot 15. Hence, the metallic gate 13 may establish a capacitive coupling to the second double quantum dot 15 that may act as a variable capacitance. A third and fourth metallic islands 14, 16 may couple several quantum dots to each other. For example, the third metallic island 14 may couple the second double quantum dot 15 to a third double quantum dot (not shown in FIG. 4) e.g. via the bus 1. There may also be more metallic islands and double quantum dots than what is shown in FIG. 4.

FIG. 5 is an illustration of another possible realization of the capacitive coupling. In this example a first double quantum dot 12 is coupled to a first metallic island 13 deposited in another layer so that the first metallic island 13 covers the area of mostly one quantum dot 12. This first metallic island 13 may establish a capacitive coupling to a second double quantum dot 15 that may act as a variable capacitance. A second metallic island 14 may be used to couple the second double quantum dot 15 to yet another double quantum dot. A number of metallic islands 13, 14 may be used to establish coupling between a plurality of quantum dots. The positioning of the second island 14 may be used to enable a change of the coupling from “ferromagnetic” to “antiferromagnetic” only by changing the capacitance between one of the first islands 13 and the second island 14.

FIG. 6 depicts an example of a layout of a Boltzmann machine 600 incorporating several layers such that a multipartite connectivity graph is realised. In this example the Boltzmann machine 600 comprises among other things a number of double quantum dots QB1-QB9, and a number of buses BUS1-BUS3. The qubits QB1-QB6 share a first bus BUS1, the qubits QB4-QB9 share a second bus BUS2, and the qubits QB7-QB9 share a third bus BUS3. Hence, part of the qubits have been connected to two buses. For example, in the implementation of FIG. 6 the qubits QB4-QB6 are connected to the first bus BUS1 and to the second bus BUS2, and the qubits QB7-QB9 are connected to the second bus BUS2 and to the third bus BUS3. It should be noted here that in practical implementations the Boltzmann machine may comprise more qubits and buses than what is illustrated in FIG. 6.

FIG. 7 is an illustration of a possible connectivity involving several bus couplers. In FIG. 7 the dots represent qubits and the lines represent the bus couplers.

FIG. 8 illustrates an arrangement of gates that enables tuning of the variable capacitance and the bias for the qubit. Two or more gates G1-G6 may be used to provide individual control for each qubit. For example, if two gates were used, they could be the gates labelled G1 and G4 in FIG. 8. The gate G5 would have the same value for all qubits. On the other hand, greater control of the capacitance might be obtained by using the gate G1 and the gate G2, and when using gates G1 and G3 in a symmetric fashion may increase stability.

FIG. 9 depicts a circuit diagram of an example of a multiplexer 900 which may be used to provide control signals to the gates. The multiplexer 900 may charge the capacitors C with different voltages. A voltage V0 is applied to the input 902 of the multiplexer 900. The control inputs 904, 906, 908 determine which output line receives the voltage V0 by supplying certain voltages at the control inputs 904, 906, 908. For example, keeping the control inputs 904, 906, 908 at a low potential (e.g. about 0V) may connect the voltage V0 to the first output 910, supplying a control voltage (e.g. 3V) to the first control input 904 and keeping the other control inputs 906, 908 at a low potential (e.g. about 0V) may connect the voltage V0 to the first output 911, supplying the control voltage to the second control input 906 and keeping the other control inputs 904, 908 at a low potential may connect the voltage V0 to the second output 912, supplying the control voltage to the first control input 904 and to the second control input 906 and keeping the third control input 908 at a low potential may connect the voltage V0 to the third output 913, etc. In other words, the voltages at the control inputs 904, 906, 908 may operate as a binary control signal (000, 001, . . . , 111) which determines which output 911-918 may receive the voltage V0.

When the voltage V0 is provided to an output 911-918 of the multiplexer 900, the capacitor C associated with that output will charge to substantially the voltage V0. The procedure can be repeated with a different voltage V0 for a different output line. The switch SW1 may be used to switch off the connection of the capacitors C to the multiplexer 900 to minimize discharging of the capacitors. The output lines 904 at potentials V1-V8 are connected to the control gates G1-G8.

FIG. 10 depicts an example implementation of the multiplexer 900. The conductors 921 may be gated by the control inputs 922 through applying voltages to the control inputs B1-B4. That means by applying voltages to lines B1-B4 a path from V0 to V1-V16 can be selected and the appropriate capacitor can be charged. When all capacitors are charged to the correct voltage at the control input B4 can be used to act as a switch to disconnect the capacitors from the charging lines as was illustrated with the switch SW1 in FIG. 9.

FIG. 11 depicts an example of a qubit readout mechanism 100 using a quantum point contact 113. The quantum point contact 113 is placed in the vicinity of a double quantum dot qubit 12. A gate 111 controls the potential on the upper quantum dot 12a. The current I through the quantum point contact 113 depends on the location of the charge on the double quantum dot 12. A higher current may be observed when the charge is located in the upper dot 12a, and a lower current may be observed when the charge is in the lower dot 12b. If the electron is located on the upper dot 12a, decreasing the gate voltage Vg may result in moving the electron to the lower dot 12b. If the electron is located on the lower dot 12b decreasing the gate voltage Vg may not influence the location of the electron.

FIG. 12 depicts an example of an electrical circuit diagram of a readout mechanism 100. All quantum point contacts 113 are connected in parallel and are biased with the voltage V. The current I through all quantum point contacts 113 is monitored to determine the state of the individual double quantum dots.

FIGS. 13a-13c illustrate an example of operation of a readout scheme. FIG. 13a depicts gate voltages, FIG. 13b depicts total current through the quantum point contacts 113 and FIG. 13c depicts the derivative of the total current through the quantum point contacts 113. The readout of the status is based on time multiplexing. Each qubit gate voltage is ramped at a certain time by providing the proper voltage V1-V16 to the corresponding gate of the double quantum dot under examination. If the electron in that particular double quantum dot is in the upper dot 12a it will move to the lower dot 12b and the total current through the quantum point contacts 113 will decrease. If an electron is already located in the lower dot 12b no change in the current will occur. Thus the value of the derivative of the total quantum point contacts 113 current at certain times is directly related to the qubit value.

In the example of FIGS. 13a-13c the status of three qubits are read by controlling the multiplexer to supply a proper voltage Vg to the control gate of each qubit one at a time. The number 1 in FIG. 13a illustrates that at that moment of time the voltage −Vg is supplied to the control gate of the first qubit. Correspondingly, the number 2 in FIG. 13a illustrates that at that moment of time the voltage −Vg is supplied to the control gate of the second qubit, and the number 3 in FIG. 13a illustrates that at that moment of time the voltage −Vg is supplied to the control gate of the third qubit. It should be noted, however, that the voltage −Vg need not be the same for each qubit but different voltages may be supplied to different gates.

FIG. 14 depicts an example layout of a functional 8 bit quantum annealing cell 140. The cell comprises several layers wherein some of the elements are implemented at different layers. For example, the voltage input V0, the qubits, the control gates of the qubits and a part of the readout structure may be implemented in one layer, the control inputs of the multiplexer and another part of the readout structure may be implemented in a second layer, and the metallic or superconducting islands for the qubits may be implemented in a third layer. The voltage applied to the voltage line can be routed to different gates using the select control input lines, thereby adjusting the biases and coupling strengths. The tunneling between computational basis states can be controlled by a control gate such as a tunneling line of the readout structure. The parallel quantum point contacts are connected to the readout line. A scale bar shows the approximate size of the circuit according to this example implementation.

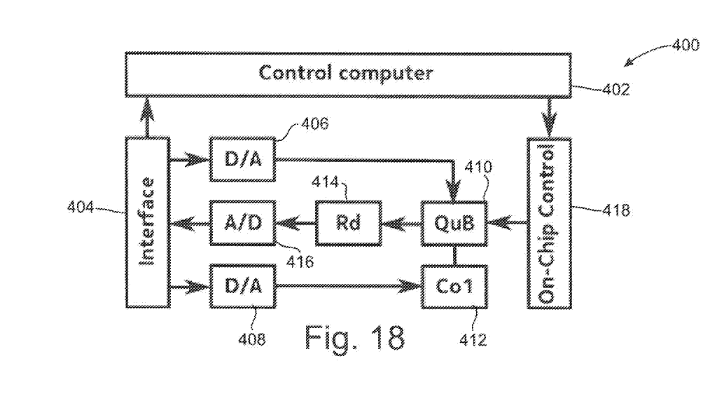

An example of initializing an adiabatic quantum optimization device 400 is described with reference to FIG. 18. The problem Hamiltonian may be encoded in the biases of individual qubits and the couplings between qubits. These values may be programmed before an annealing run. The biases of the qubits 410 may be programmed from a control computer 402 via an interface 404 and a D/A conversion stage 406 and, respectively, the couplings 412 between the qubits 410 may be programmed from the control computer 402 via the interface 404 and another D/A conversion stage 408. Similarly the final state of the qubits 410 after the annealing run may be read and sent to the control computer 402. This may be achieved e.g. by a state reading unit 414, which may obtain states of the qubits 410 as analog signals. The analog signals may then be converted to digital form by an A/D conversion stage 416. Additionally, the change of parameters during an annealing run may be controlled by an on-chip control unit 418. An annealing run can be initiated on demand from the control computer 402.

All the elements of the apparatus of FIG. 18 beside the control computer may be implemented on a single chip using superconducting electronics.

FIG. 17 illustrates an example of a computing device 200 in which the quantum computing circuitry 202 may be utilized. The computing device 200 comprises the quantum computing circuitry 202 having one or more sets of qubits and a number of control gates for providing control signals to the qubits and to the multiplexer of the quantum computing circuitry 202. The control gates may be connected to an interface circuitry 204 which comprises means for providing information to the quantum computing circuitry 202 and for obtaining information from the quantum computing circuitry 202. The information to be provided to the quantum computing circuitry 202 may comprise program instructions, initial values for the qubits and/or other data. Information obtained from the quantum computing circuitry 202 may comprise e.g. computation results.

The interface circuitry 204 may comprise inter alia analog-to-digital converters and digital-to-analog converters for converting digital values to analog signals (e.g. to currents) and for converting analog signals (e.g. to currents) to digital values, respectively.

The computing device 200 may also comprise a display 210 for displaying information to the user, and a keyboard 212 and/or another input device so that the user may control the operation of the computing device 200 and input parameters, variables etc. to be used by the quantum computing circuitry 202. There may also be communication means 214 for communicating with a communication network such as the internet, a mobile communication network and/or another wireless or wired network.

There may also be provided a processor 216 for controlling the operation of the computing device and the elements of the computing device.

During operation the quantum computing circuitry 202 is cooled down to a temperature in which the elements of the quantum computing circuitry, inter alia the qubits, couplers and the bus become superconducting due to the properties of the materials used in producing the elements. The quantum computing circuitry 202 may be installed in a dilution refrigerator 206, for example. The dilution refrigerator 206 may be able to be cooled down to the temperature of a few mK, for example to 20 mK or below.

The term computer-readable medium is used herein to refer to any medium that participates in providing information to processor 216, including instructions for execution. Such a medium may take many forms, including, but not limited to, non-volatile media, volatile media and transmission media. Non-volatile media include, for example, optical or magnetic disks, such as storage device. Volatile media include, for example, dynamic memory 218. Transmission media include, for example, coaxial cables, copper wire, fiber optic cables, and carrier waves that travel through space without wires or cables, such as acoustic waves and electromagnetic waves, including radio, optical and infrared waves. Signals include man-made transient variations in amplitude, frequency, phase, polarization or other physical properties transmitted through the transmission media. Common forms of computer-readable media include, for example, a floppy disk, a flexible disk, hard disk, magnetic tape, any other magnetic medium, a CD-ROM, CDRW, DVD, any other optical medium, punch cards, paper tape, optical mark sheets, any other physical medium with patterns of holes or other optically recognizable indicia, a RAM, a PROM, an EPROM, a FLASH-EPROM, any other memory chip or cartridge, a carrier wave, or any other medium from which a computer can read.

Embodiments of the present invention may be implemented in software, hardware, application logic or a combination of software, hardware and application logic. In an example embodiment, the application logic, software or an instruction set is maintained on any one of various conventional computer-readable media. In the context of this document, a “computer-readable medium” may be any media or means that can contain, store, communicate, propagate or transport the instructions for use by or in connection with an instruction execution system, apparatus, or device, such as a computer, with one example of a computer described and depicted in FIGS. 17 and 18. A computer-readable medium may comprise a computer-readable storage medium that may be any media or means that can contain or store the instructions for use by or in connection with an instruction execution system, apparatus, or device, such as a computer.

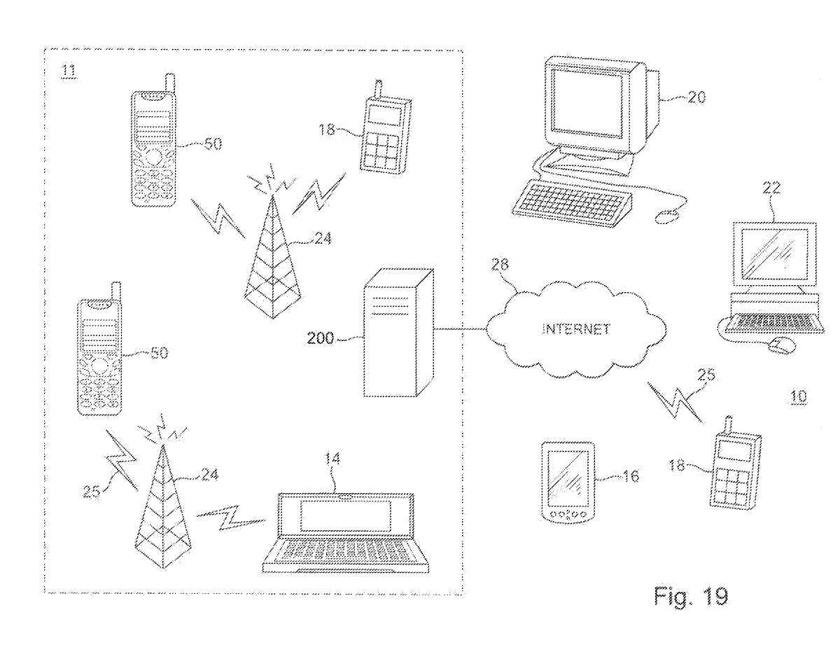

With respect to FIG. 19, an example of a system within which embodiments of the present invention can be utilized is shown. The system 10 comprises multiple communication devices which can communicate through one or more networks with the computing device 200. the communication devices may provide operating instructions, parameters, algorithms etc. to the use of the computing device 200 and receive calculation results from the computing device 200.

The system 10 may comprise any combination of wired and/or wireless networks including, but not limited to a wireless cellular telephone network (such as a GSM, UMTS, CDMA network etc.), a wireless local area network (WLAN) such as defined by any of the IEEE 802.x standards, a Bluetooth personal area network, an Ethernet local area network, a token ring local area network, a wide area network, and the Internet, to communicate with the computing device 200. However, the computing device 200 may not need any communication connection to a communication network wherein the computing device 200 may be controlled and operated locally by the user interface.

For example, the system shown in FIG. 19 shows a mobile telephone network 11 and a representation of the internet 28. Connectivity to the internet 28 may include, but is not limited to, long range wireless connections, short range wireless connections, and various wired connections including, but not limited to, telephone lines, cable lines, power lines, and similar communication pathways.

The example communication devices shown in the system 10 may include, but are not limited to, an electronic device or apparatus 50, a combination of a personal digital assistant (PDA) and a mobile telephone 14, a PDA 16, an integrated messaging device (IMD) 18, a desktop computer 20, a notebook computer 22. The apparatus 50 may be stationary or mobile when carried by an individual who is moving. The apparatus 50 may also be located in a mode of transport including, but not limited to, a car, a truck, a taxi, a bus, a train, a boat, an airplane, a bicycle, a motorcycle or any similar suitable mode of transport.

In general, the various embodiments of the invention may be implemented in hardware or special purpose circuits or any combination thereof. While various aspects of the invention may be illustrated and described as block diagrams or using some other pictorial representation, it is well understood that these blocks, apparatus, systems, techniques or methods described herein may be implemented in, as non-limiting examples, hardware, software, firmware, special purpose circuits or logic, general purpose hardware or controller or other computing devices, or some combination thereof.

Embodiments of the inventions may be practiced in various components such as integrated circuit modules. The design of integrated circuits is by and large a highly automated process. Complex and powerful software tools are available for converting a logic level design into a semiconductor circuit design ready to be etched and formed on a semiconductor substrate.

Programs, such as those provided by Synopsys, Inc. of Mountain View, Calif. and Cadence Design, of San Jose, Calif. automatically route conductors and locate components on a semiconductor chip using well established rules of design as well as libraries of pre stored design modules. Once the design for a semiconductor circuit has been completed, the resultant design, in a standardized electronic format (e.g., Opus, GDSII, or the like) may be transmitted to a semiconductor fabrication facility or “fab” for fabrication.

While the invention has been described in connection with a number of embodiments and implementations, the invention is not so limited but covers various obvious modifications and equivalent arrangements, which fall within the purview of the appended claims. Although features of the invention are expressed in certain combinations among the claims, it is contemplated that these features can be arranged in any combination and order.

1-13. (canceled)

14. An apparatus comprising:
a first quantum dot and a second quantum dot forming a first kind of double quantum dot;
a third quantum dot and a fourth quantum dot forming a second kind of double quantum dot for providing adjustable capacitance for the first double quantum dot;
a first control element for adjusting the capacitance of the second kind of double quantum dot;
a second control element for supplying a control voltage to the first kind of double quantum dot;
a metallic or superconducting contact capacitively coupled to the fourth quantum dot; and
an electric charge sensor for providing an indication of the state of the first kind of double quantum dot.

15. The apparatus according to claim 14, wherein the third and fourth quantum dots are adapted to change an effective capacitance of the adjustable capacitance from positive to negative.

16. The apparatus according to claim 14, wherein the apparatus comprises a plurality of double quantum dots capacitively coupled to the metallic or superconducting contact.

17. The apparatus according to claim 16 further comprising a multiplexer having:
a first input for receiving a control voltage;
a second input for receiving a selection signal; and
a plurality of outputs, wherein the apparatus is adapted to select the output on the basis of the selection signal for supplying the control voltage to charge a capacitance of a selected second control element of the plurality of double quantum dots.

18. The apparatus according to claim 14 further comprising:
a second capacitive element for providing a coupling from the second kind of double quantum dot to a third double quantum dot.

19. The apparatus according to claim 14 further comprising:
a control gate for controlling tunneling in the first kind of double quantum dots between their computational basis states.

20. The apparatus according to claim 14, wherein the electric charge sensor is adapted to provide a current dependent on a location of a charge in the first kind of double quantum dot.

21. An adiabatic quantum annealing apparatus comprising a plurality of apparatuses according to claim 14.

22. A method comprising:
supplying a control voltage to a plurality of first kind of double quantum dots of an apparatus, said first kind of double quantum dots comprising a first quantum dot and a second quantum dot;
adjusting a capacitance of the plurality of first kind of double quantum dots to a metallic or superconducting contact by using a plurality of second kind of double quantum dots;
decreasing tunneling in the first kind of double quantum dots; and
using an electric charge sensor for obtaining an indication of the state of the first kind of double quantum dots.

23. The method according to claim 22, wherein the indication is obtained by measuring a current flowing through the electric charge sensor.

24. The method according to claim 22 further comprising:
providing a control voltage to a first input of a multiplexer;
providing a selection signal to a second input of the multiplexer for selecting an output among a plurality of outputs for supplying the control voltage to a control element of one of the plurality of double quantum dots on the basis of the selection signal;
providing the control voltage to charge a capacitance of the control element of the selected double quantum dot.

25. The method according to claim 22 further comprising:
applying the control voltage to control gates of the plurality of first kind of double quantum dots;
applying a bias voltage to a control gate of the electric charge sensor;
obtaining an indication of the current flowing through the electric charge sensor.

26. An apparatus comprising:
a first quantum dot and a second quantum dot forming a first kind of double quantum dot;
a third quantum dot and a fourth quantum dot forming a second kind of double quantum dot for providing adjustable capacitance for the first double quantum dot;
means for adjusting the capacitance of the capacitive element;
means for supplying a control voltage to the first kind of double quantum dot;
means for coupling the first kind of double quantum dot to a metallic or superconducting contact; and
means for providing an indication of the state of the first kind of double quantum dot.
